(19) United States
(12) Patent Application Publication
(10) Pub. No.: US 2006/0088954 A1
(43) Pub. Date: Apr. 27, 2006

(54) Electronic component with cavity fillers made from thermoplast and method for production thereof

(76) Inventors: Michael Bauer, Nittendorf (DE); Christian Birzer, Burglengenfeld (DE); Gerald Ofner, Regensburg (DE); Stephan Stoeckl, Schwandorf (DE)

Correspondence Address: DICKE, BILLIG & CZAJA, P.L.L.C., FIFTH STREET TOWERS, 100 SOUTH FIFTH STREET, SUITE 2250, MINNEAPOLIS, MN, 55402, US

(21) Appl. No.: 10/515,517

(22) PCT Filed: Oct. 20, 2003
(86) PCT No.: PCT/DE03/03463

§ 371 Date: Aug. 29, 2005

(30) Foreign Application Priority Data
Oct. 29, 2002 (DE) 102 50 541.1

(51) Int. Cl. H01L 21/48; H01L 21/50

(52) U.S. Cl. 438/108; 438/127; 438/124; 438/126

(57) ABSTRACT

An electronic component and a method for fabricating it is disclosed, where the component comprises a semiconductor chips which has flip-chip contacts. These contacts are fixed on a rewiring substrate, the interspace between the rewiring substrate and the semiconductor chip being filled with a thermoplastic. The glass transition temperature of the thermoplastic is above the highest operating test temperature of the component and below the melting temperature of the solder material for external contacts.

### FIELD OF THE INVENTION

The invention relates to an electronic component with a semiconductor chip which has flip-chip contacts and is fixed on a rewiring substrate, and also to a method for fabricating it.

### BACKGROUND

Electronic components with flip-chip contacts and a rewiring substrate are packaged in a plastic package made of thermosetting plastics. When external contacts are attached to external contact pads on the rewiring substrate of such electronic components or when the finished external contacts are soldered onto a circuit carrier, some of these electronic components fail unexpectedly, even though their operability has been successfully tested beforehand for temperature cycles between a top operating test temperature of approximately plus 150° C. and a bottom operating test temperature of approximately minus 50° C.

### SUMMARY

The invention provides an electronic component with underfillers made of thermoplastics, and method for fabricating the electronic component.

It is an object of the invention to specify an electronic component and a method for fabricating it which increases the reliability of electronic components.

This object is achieved by means of the subject matter of the independent claims. Advantageous developments can be found in the dependent claims.

The invention provides an electronic component having a semiconductor chip which has flip-chip contacts on its active top side which are fixed to contact pads on a rewiring substrate. This fixing can be obtained by means of a solder connection and/or using a conductive adhesive. The interspace formed between the rewiring substrate and the semiconductor chip by the flip-chip contacts has a thermoplastic as an underfiller. The glass transition temperature of this thermoplastic used as an underfiller is below the melting temperature of the solder material of the external contacts on the electronic component.

Such a component has the advantage that the instances of failure of the electronic components are reduced when soldering external contacts onto external contact pads and when soldering external contacts on the electronic component onto circuit carriers. When a thermoplastic is added which exceeds its glass transition temperature and softens during soldering operations in the region of the external contacts and, upon reaching the soldering temperature, changes to a liquid state, the effect achieved is that stresses resulting from vapor phase formation in the case of duraplastic materials as plastic package compound are toned down. The softened thermoplastic is able to deform plastically and hence to yield without destroying the joints between flip-chip contacts on the semiconductor chip and contact connection pads on a rewiring substrate. Hence, the failure rate when soldering external contacts or when soldering onto circuit carriers is reduced.

In all cases, however, the glass transition temperature and hence the softening point is above the highest operating test temperature for electronic components, which may be between 70 and 150° C., depending on the area of application. Consumer components are not tested so hard, and hence are tested at a lower maximum operating test temperature than commercial components, such as electronic components for automotive engineering, which are cyclically subjected to a maximum operating test temperature of 150° C. during the operating test. The glass transition temperature for the thermoplastic provided as an underfiller then also needs to be chosen to be correspondingly higher.

A further advantage of this electronic component is that the package no longer needs to be predried before each soldering process in order to expel moisture, since a higher level of moisture can be tolerated when a thermoplastic is used as underfiller, without the joint or the structure of the component being destroyed.

The thermoplastic used may be one of the materials from the group comprising polyamide, polyacetal, polycarbonate, polyethylene, polypropylene, polyethylene terephthalate or mixtures thereof. Particularly by mixing these thermoplastics, it is possible to set the desired softening temperature range and melting temperature range. This ensures that the thermoplastic has the same strength at the maximum operating test temperature as at room temperature, especially since the glass transition temperature for the thermoplastic is not reached until above this point.

In contrast to soldering, where only parts of an electronic component are heated and only parts of it can reach critical temperatures, for the operating test the electronic components are exposed fully to a maximum operating test temperature, which may be 150° C. At such a temperature, the thermoplastic needs to have the same consistency and strength as at room temperature. Only at the much higher soldering temperature of the external contacts, which may reach 250° C., does the thermoplastic as underfiller have a plastic compliance or liquid properties which prevent the components of the electronic component, particularly the semiconductor chip, the flip-chip contacts and the contact pads on the rewiring substrate, from being damaged or destroyed, or their interconnections from being broken.

A plastic package containing the semiconductor chip and the flip-chip contacts may have a thermoplastic with the same glass transition temperature as the underfiller. This has the advantage that the plastic package and the underfiller can be introduced in a single transfer molding step.

Before they are introduced, the flip-chip contacts can be securely fixed on appropriate contact pads on the rewiring substrate, especially since the inventive design of the electronic component allows the package to be fabricated without the need for the semiconductor chip to be pressed onto appropriate contact pads on the rewiring substrate by plastic film or plastic layer before it is packaged with its flip-chip contacts.

The plastic package may also comprise a thermoplastic with a glass transition temperature which is above the melting temperature of the solder material for the external contacts. In this case, when certain parts have reached the soldering temperature, only the thermoplastic used as an underfiller (which thermoplastic softens at a lower temperature) will yield as it softens or becomes liquid. However, this plastic yielding by the underfiller is sufficient to prevent the connections between semiconductor chip and rewiring substrate from being damaged or destroyed. In this case, two successive transfer molding processes are required in order to apply the two different thermoplastics firstly as an underfiller and then as a plastic package.

Advantageously, the thermoplastic may be in a liquid state in a temperature range between 200° C. and 220° C. In such a liquid state, the thermoplastic is sufficiently compliant for stresses resulting from the formation of water vapor to be compensated for. In addition, this temperature range is clearly above a maximum operating test temperature and below a soldering temperature for the external contacts.

A method for fabricating an electronic component has the following method steps: first, a rewiring substrate with contact pads on its top side and external contact pads on its underside is fabricated. In the rewiring substrate, the external contact pads on the underside are connected to the contact pads on the top side of the rewiring substrate via through holes and via rewiring lines. In addition, a semiconductor chip using flip-chip technology is fabricated with flip-chip contacts on its active top side.

If both the rewiring substrate and the semiconductor chip with flip-chip contacts are available, then the flip-chip contacts are put onto the rewiring substrate and are electrically connected to the contact pads. Finally, the interspace between the active top side of the semiconductor chip and the top side of the rewiring substrate can be filled with an underfiller made of thermoplastic.

This method has the advantage that filling the interspace between the semiconductor chip and the rewiring substrate does not involve the use of a thermosetting plastic which, particularly when soldering external contacts or when soldering the external contacts onto a circuit carrier, might damage or destroy the connection between semiconductor chip and rewiring substrate when moisture occurs.

The flip-chip contacts may be soldered onto the contact pads on the rewiring substrate or may be fixed using a conductive adhesive before the thermoplastic is introduced as underfiller. Since this method step takes place even before the underfiller is introduced, a secure, reliable electrical connection can be provided by means of the flip-chip contacts to the rewiring substrate and hence to the external contact pads on the rewiring substrate.

The underfiller may be applied with appropriate heating using dispersion technology, which means that it is possible to dispense with a high-pressure mold. If the plastic package is made of the same material as the underfiller, then the plastic package can be produced at the same time as the underfiller. In this case, it is advantageous to apply the thermoplastic using injection-molding technology, which means that it is possible to underfill and mold the plastic package in one step.

Before the thermoplastic is introduced onto the top side of the rewiring substrate, it is heated to a processing temperature above the maximum operating test temperature and below the melting temperature of the solder material for external contacts. Preferably, provision is made for the thermoplastic to be heated to temperatures between 200 and 220° C. before it is applied to the rewiring structure.

### BRIEF DESCRIPTION OF THE DRAWINGS

The invention will now be explained in more detail with reference to the accompanying figures.

FIG. 1 illustrates a schematic cross section through an electronic component which has been put onto a circuit carrier.

FIG. 2 illustrates a schematic cross section through a critical portion of an electronic component.

FIG. 3 illustrates a schematic cross section through an electronic component with a plastic package which has been put onto a circuit carrier.

### DETAILED DESCRIPTION

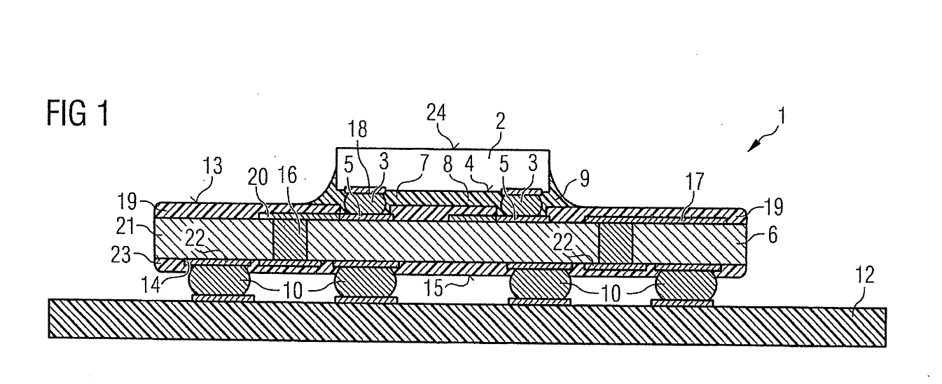

FIG. 1 illustrates a schematic cross section through an electronic component 1 which has been put onto a circuit carrier 12 for a electronic circuit by its external contacts 10. The electronic component 1 essentially comprises two main components, namely a semiconductor chip 2 and a rewiring substrate 6.

The rewiring substrate 6 essentially has five layers. Starting from its top side 13, the five layers are staggered down to the underside 15 as follows: an upper solder resist layer 19, an upper rewiring layer 20, an electrically insulating core plate 21, a lower rewiring layer 22 and a lower solder resist layer 23. The lower solder resist layer 23 covers the underside 15 of the rewiring substrate 6 as far as external contact pads 13, on which external contacts 10 in the form of solder balls are soldered. The external contact pads 14 are part of the lower rewiring layer 22, which is electrically connected to the upper rewiring layer 20 by means of through holes 16. The upper solder resist layer 19 leaves only the contact pads 5 on the upper rewiring layer 20 free of solder resist.

The semiconductor chip 2 has an active top side 4 and a passive reverse side 24. The active top side 4 has contact pads 18 arranged on it which carry flip-chip contacts 3 in the form of solder balls or bumps. The two main components of the electronic component 1 are electrically interconnected by means of the flip-chip contacts 3 on the semiconductor chip 2 and the contact pads 5 on the upper rewiring layer 20 of the rewiring substrate 6. An interspace 7 which forms between the active top side 4 of the semiconductor chip 2 and the top side 13 of the rewiring substrate 6 is filled with a thermoplastic 8.

This thermoplastic 8 or the mixture of thermoplastics has a glass transition temperature between 155° C. and 250° C. The critical phase when assembling an electronic component 1 of this type and when adding an electronic component 1 of this type to the top side of a circuit carrier 12 is when the external contacts 10 are heated to soldering temperature.

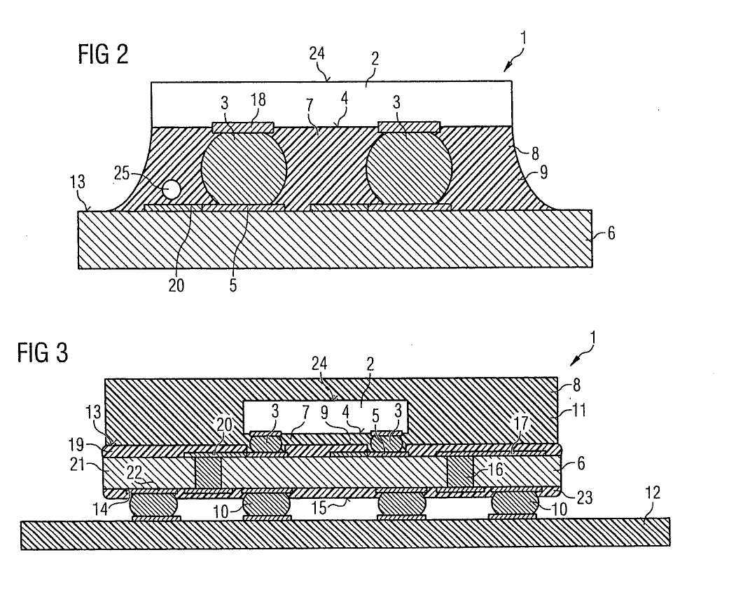

FIG. 2 illustrates a schematic cross section through a critical portion of an electronic component 1. This critical portion is the interspace 7 between the active top side 4 of the semiconductor chip 2 and the top side 13 of the rewiring substrate 6. This interspace has a permanent connection in the form of flip-chip contacts 3 between the contact pads 18 on the semiconductor chip 2 and contact pads 5 on the upper rewiring layer 20 of the rewiring substrate 6. Since plastics are hygroscopic, they absorb moisture when there are interlayer deposits.

When soldering external contacts (not shown in FIG. 2) of the electronic component, vapor bubbles 25 may form and exert a pressure on the top sides of the rewiring substrate 6 and the semiconductor chip 2, which are connected by means of the flip-chip contacts 3. An underfiller 9 made of the thermoplastic 8 filling the interspace 7 may yield to this pressure, especially since it is plastically compliant or liquid in the region of the soldering temperature and may thus alleviate the stress resulting from a vapor bubble 25 of this type.

The risk of the electrical connection of the flip-chip contacts 3 being separated from the contact pads 5 on the rewiring substrate 6 is lessened. Rather, the electrical connection is maintained both when soldering the external contacts to the external contact pads, as are shown in FIG. 1, and when soldering the electronic component onto a circuit carrier.

FIG. 3 illustrates a schematic cross section through an electronic component 1 with a plastic package 11 which has been put onto a circuit carrier 12. Components having the same functions as in the preceding figures are identified by the same reference symbols and are not discussed separately.

The difference between this electronic component 1 and the component 1 shown in FIG. 1 is that the passive reverse side of the semiconductor chip 2 is not freely accessible as in FIG. 1, but rather is covered with a plastic package 11. In this embodiment of the invention shown in FIG. 3, this plastic package 11 comprises the same thermoplastic 8 as that from which the underfiller 9 is already formed. The underfiller 9 and the plastic package 11 were put on in a single transfer molding step. To avoid possible partial deformation or melting of the plastic package 11 during soldering, the plastic package 11 can be cooled to some extent during the soldering operation.

What is claimed is:

1-9. (canceled)

10. A method for fabricating an electronic component, comprising:
providing a rewiring substrate, having contact pads on its top side;
providing a semiconductor chip in flip-chip technology having flip-chip contacts on its active top side;
applying and electrically connecting the flip-chip contacts to the contact pads of the rewiring substrate;
substantially filling an interspace between the active top side of the semiconductor chip and the top side of the rewiring substrate with an underfiller which comprises a thermoplastic.

11. The method of claim 10, comprising soldering the flip-chip contacts onto the contact pads before the underfiller is introduced.

12. The method of claim 10, comprising:
applying, essentially simultaneously with the introduction of the underfiller, a plastic package made of the same thermoplastic material in order to package the semiconductor chip.

13. The method of claim 10 comprising:
heating the thermoplastic, prior to being applied to the rewiring substrate, to temperatures below the melting temperature of the solder material for external contacts, preferably to temperatures between 200° C. and 220° C., and is changed to a liquid state.

14. The method of claim 10, comprising: applying the thermoplastic as the underfiller using dispersion technology.

15. The method of claim 10, comprising:
Applying the thermoplastic as underfiller using injection-molding technology.

16. A method for fabricating an electronic component, comprising:
providing a rewiring substrate, having contact pads on its top side;
providing a semiconductor chip in flip-chip technology having flip-chip contacts on its active top side;
applying and electrically connecting the flip-chip contacts to the contact pads of the rewiring substrate;
substantially filling an interspace between the active top side of the semiconductor chip and the top side of the rewiring substrate with an underfiller which comprises a thermoplastic;
soldering the flip-chip contacts onto the contact pads before the underfiller is introduced; and
heating the thermoplastic, prior to being applied to the rewiring substrate, to temperatures below the melting temperature of the solder material for external contacts, preferably to temperatures between 200° C. and 220° C., and is changed to a liquid state.

17. The method of claim 16, comprising:
applying, essentially simultaneously with the introduction of the underfiller, a plastic package made of the same thermoplastic material in order to package the semiconductor chip.

18. The method of claim 16, comprising:
applying the thermoplastic as the underfiller using dispersion technology.

19. The method of claim 16, comprising:
Applying the thermoplastic as underfiller using injection-molding technology.

20. An electronic component comprising:
a semiconductor chip which has flip-chip contacts on its active top side which are fixed on contact pads on a rewiring substrate;
an underfiller within the interspace between the rewiring substrate and the semiconductor chip which arises as a result of the flip-chip contacts, the underfiller comprising a thermoplastic whose glass transition temperature is below a melting temperature of a solder material of external contacts of the electronic component.

21. The electronic component of claim 20, wherein the thermoplastic comprises at least one material from the group comprising polyamide, polyacetal, polycarbonate, polyethylene, polypropylene, polyethylene terephthalate or mixtures thereof.

22. The electronic component of claim 20, wherein a plastic package for the electronic component comprises a thermoplastic having the same glass transition temperature as the underfiller.

23. The electronic component of claim 20, wherein the thermoplastic is in a liquid state in a temperature range between 200° C. and 220° C.

24. An electronic component comprising:
a rewiring substrate having an upper solder resist layer, an upper rewiring layer, an electrically insulating core plate, a lower rewiring layer and a lower solder resist layer;
a semiconductor chip which has flip-chip contacts on its active top side which are fixed on contact pads on the rewiring substrate;
an underfiller within the interspace between the rewiring substrate and the semiconductor chip which arises as a result of the flip-chip contacts, the underfiller comprising a thermoplastic whose glass transition temperature is below a melting temperature of a solder material of external contacts of the electronic component.

25. The electronic component of claim 24, wherein the thermoplastic comprises at least one material from the group comprising polyamide, polyacetal, polycarbonate, polyethylene, polypropylene, polyethylene terephthalate or mixtures thereof.

26. The electronic component of claim 25, wherein a plastic package for the electronic component comprises a thermoplastic having the same glass transition temperature as the underfiller.

27. The electronic component of claim 24, wherein the thermoplastic is in a liquid state in a temperature range between 200° C. and 220° C.

28. The electronic component of claim 24, further comprising:
a circuit carrier having an electronic circuit, coupled to the electronic components via external contacts.

29. An electronic component comprising:
a semiconductor chip which has flip-chip contacts on its active top side which are fixed on contact pads on a rewiring substrate;
means for underfilling, within the interspace between the rewiring substrate and the semiconductor chip which arises as a result of the flip-chip contacts, the underfiller means comprising a thermoplastic whose glass transition temperature is below a melting temperature of a solder material of external contacts of the electronic component.

30. The electronic component of claim 16, wherein the thermoplastic comprises at least one material from the group comprising polyamide, polyacetal, polycarbonate, polyethylene, polypropylene, polyethylene terephthalate or mixtures thereof.
